(19) United States
(12) Patent Application Publication
(10) Pub. No.: US 2019/0162491 A1
(43) Pub. Date: May 30, 2019

(54) Anisotropic Flexible Thermal Interface Pad and Method for Fabricating the Same

(71) Applicant: HFC INDUSTRY LIMITED, Hong Kong (CN)

(72) Inventors: Ai Xiang SUN, Shenzhen (CN); Younan XIE, Shenzhen (CN); Chi Ho KWOK, Hong Kong (CN); Ning TU, Hong Kong (CN); Tsz Nok NG, Hong Kong (CN); Chenmin LIU, Hong Kong (CN)

(21) Appl. No.: 16/200,717

(22) Filed: Nov. 27, 2018

Related U.S. Application Data
(60) Provisional application No. 62/590,796, filed on Nov. 27, 2017.

(51) Int. Cl. F28F 21/02; H05K 7/20; F28F 21/06; B23P 15/26

(52) U.S. Cl. CPC F28F 21/02; H05K 7/20454; H05K 7/20481; F28F 21/065; F28D 2021/0029; F28F 2255/02; F28F 2255/06; F28F 2245/00; B23P 15/26

(57) ABSTRACT

In an anisotropic flexible thermal interface pad, a heat-conduction layer on a dielectric layer is formed by using electroflocking to attach a plurality of thermally-conductive fibers, such as carbon fibers, on the dielectric layer and sealing the fibers with a sealing agent, such as silicone. The sealing agent is less thermally-conductive than the fibers. The plurality of fibers is aligned substantially-unidirectionally to achieve a predetermined inclination angle (e.g., 90°) with respect to the dielectric layer for discouraging neighboring fibers to contact each other while maintaining efficient heat transmission along each fiber. Thus, heat is transmitted more efficiently along a direction perpendicular to the dielectric layer than along another direction in parallel thereto. The pad may include additional heat-conduction layers, each configured similar to the heat-conduction layer, stacked together thereon. Fibers in two neighboring heat-conduction layers are interconnected by partial overlapping to facilitate heat transfer between the two neighboring layers.

### CROSS REFERENCE TO RELATED APPLICATIONS

This application claims the benefit of U.S. Provisional Patent Application No. 62/590,796, filed on Nov. 27, 2017, which is incorporated by reference herein in its entirety.

### FIELD OF THE INVENTION

The present invention relates to a thermally-anisotropic thermal interface pad and a manufacturing method thereof.

### BACKGROUND

Thermal management has become an important issue for an electronic device as there is a continual increase in power density with the decrease in size of the electronic device. When heat is accumulated in electronic parts, the processing performance of the electronic device decreases and the electronic parts may be damaged. Thus, it is necessary to remove heat from the device to prevent heat accumulation and creation of excessively hot spot(s) in the device. Therefore, at least some parts of the device are required to have a high thermal conductance. Traditionally, the heat generated by the electronic device is removed by a metal heat sink. When a heat-generating electronic component and the metal heat sink are placed into contact, a perfect contact cannot be created at the interface since contacting surfaces of the electronic component and the heat sink nevertheless have minute, uncorrelated surface roughness, resulting in a poor thermal contact. Thus, the interface between the heat sink and the electronic component requires a soft and deformable material to be present in order to reduce the size of any present air gap at the interface. Such material is called a thermal interface material (TIM), which may be a thermally conductive sheet, a paste of thermally conductive grease, a layer of thermally conductive adhesive, a phase change material, etc. Forming a TIM with anisotropic thermal conductance behavior along two orthogonal directions (typically, a lateral direction along a sheet of TIM and a vertical direction perpendicular to the sheet) is a great challenge.

CN106518083A discloses a thermally-anisotropic silicon carbide (SiC) composite ceramic block and a preparation method thereof. The block is prepared by heating a mixture of SiC, a layer-shaped carbon material and other fillers at a temperature of 1600° C. to 1800° C. under an upward pressure (i.e. a pressure along one direction) of 20 MPa to 30 MPa. Applying a high directional pressure in the presence of 1600° C. or more in temperature is costly and difficult.

WO2016/178120A1 discloses a polyester film dispersed with thermally-anisotropic filler particles, where the filler particles are aligned so as to introduce thermal anisotropy to the polyester film. However, manufacturing the film involves melting polyester to incorporate the filler particles so as to give a polyester film dispersed with the filler particles. Polyester has a melting point of around 260° C. To those skilled in the art, if it is desired to reduce manufacturing cost, a manufacturing process not requiring melting raw materials is more preferable.

CN105906844A discloses a thermally-anisotropic composite material that can be manufactured by a process involving heating of at most 80° C. without melting raw materials. Thermal anisotropy of the composite material is achieved by aligning graphene flakes, which are themselves thermally anisotropic, based on confining orientations of the graphene flakes by liquid crystals (LCs). However, the composite material may not be suitable for use in manufacturing TIMs in some electronic devices due to toxicity of the LCs to people and chemical instability of the LCs in the presence of high temperature during device operation.

There is a need in the art to have a LC-free TIM manufactured by a process not involving melting raw materials for reducing a manufacturing cost.

### SUMMARY OF THE INVENTION

A first aspect of the present invention is to provide a thermal interface pad that is thermally-anisotropic.

The thermal interface pad comprises a dielectric layer and a first heat-conduction layer. The dielectric layer has a first side and a second side opposite thereto. The first heat-conduction layer is integrated with the dielectric layer on the first side. The first heat-conduction layer comprises a first sealing agent and a first plurality of thermally-conductive fibers randomly dispersed in the first sealing agent. The first plurality of fibers is arranged and oriented to protrude from the dielectric layer for transmitting heat therefrom or thereto. The first sealing agent has a thermal conductivity less than a thermal conductivity of the first plurality of fibers. When the dielectric layer is held planar, different fibers in the first plurality of fibers are aligned substantially-unidirectionally to achieve a predetermined inclination angle with respect to the dielectric layer for discouraging neighboring fibers in the first plurality of fibers to contact each other. As a result, heat energy to be transmitted in the first heat-conduction layer is transmitted more efficiently along a first direction perpendicular to the dielectric layer than along a second direction in parallel thereto.

Preferably, the predetermined inclination angle is in a range of 45° to 90°.

It is preferable and advantageous that the dielectric layer is thermally-conductive. The dielectric layer may contain silicone or epoxy resin. The dielectric layer may further contain fillers composed of aluminum oxide, aluminum nitride, aluminum hydroxide, boron nitride, one or more types of ceramic particles, or a combination thereof

Preferably, the thermal interface pad further comprises a first adhesive layer on the first side for binding the first plurality of fibers to the dielectric layer.

The first plurality of fibers may include carbon fibers, carbon nanotubesor a combination thereof

Preferably, the first sealing agent contains silicone or epoxy resin. The first sealing agent may further contain fillers composed of aluminum oxide, aluminum nitride, aluminum hydroxide, boron nitride, one or more types of ceramic particles, or a combination thereof.

Preferably, at least the dielectric layer and the first sealing agent are selected to be deformable so as to configure the thermal interface pad to be flexible.

According to one embodiment of the present invention, the thermal pad further comprises one or more additional heat-conduction layers stacked together on the first heat-conduction layer for transmitting heat therefrom or thereto. The first heat-conduction layer and the one or more additional heat-conduction layers form a plurality of heat-conduction layers. An individual additional heat-conduction layer comprises a respective sealing agent and a respective plurality of thermally-conductive fibers randomly dispersed in the respective sealing agent. The respective sealing agent has a thermal conductivity less than a thermal conductivity of the respective plurality of fibers. When the dielectric layer is held planar, different fibers in the respective plurality of fibers are aligned substantially-unidirectionally to achieve the predetermined inclination angle with respect to the dielectric layer for discouraging neighboring fibers in the respective plurality of fibers to contact each other. As a result, heat energy to be transmitted in the individual additional heat-conduction layer is transmitted more efficiently along the first direction than along the second direction. In addition, the two respective pluralities of fibers of any two neighboring heat-conduction layers selected from the plurality of heat-conduction layers are interconnected so as to facilitate heat transfer between the two neighboring heat-conduction layers.

Preferably, the two respective pluralities of fibers of the two neighboring heat-conduction layers are mutually partially-overlapped for achieving interconnection.

Respective sealing agents in the plurality of heat-conduction layers may or may not be made of a same material.

According to one embodiment of the present invention, the thermal interface pad further comprises a second heat-conduction layer integrated with the dielectric layer on the second side. The second heat-conduction layer comprises a second sealing agent and a second plurality of thermally-conductive fibers randomly dispersed in the second sealing agent. The second plurality of fibers is arranged and oriented to protrude from the dielectric layer for transmitting heat therefrom or thereto. The second sealing agent has a thermal conductivity less than a thermal conductivity of the second plurality of fibers. When the dielectric layer is held planar, different fibers in the second plurality of fibers are aligned substantially-unidirectionally to achieve the predetermined inclination angle with respect to the dielectric layer for discouraging neighboring fibers in the second plurality of fibers to contact each other. As a result, heat energy to be transmitted in the second heat-conduction layer is transmitted more efficiently along the first direction than along the second direction.

The first and second sealing agents may or may not be made of a same material.

A second aspect of the present invention is to provide a method for fabricating the disclosed thermal interface pad.

The method comprises: a step (a) of depositing a first adhesive layer on a first side of a dielectric layer whereby the first side is regarded as a target surface for electroflocking; a step (b) of using electroflocking to bind a plurality of thermally-conductive fibers on the target surface and to cause different fibers in said plurality of fibers to be aligned substantially-unidirectionally to achieve a predetermined inclination angle with respect to the dielectric layer for discouraging neighboring fibers in said plurality of fibers to contact each other; a step (c) of depositing a sealing agent on said plurality of fibers; and a step (d) of arranging the sealing agent to immerse into gaps among the different fibers in said plurality of fibers to form a heat-conduction layer.

The method further comprises after the step (d) is done, checking whether there is any target surface that requires fabricating an additional heat-conduction layer thereon. When it is determined that the target surface is a second side of the dielectric layer, deposit a second adhesive layer onto the target surface, and repeat the steps (b), (c) and (d). When it is determined that the target surface is an exposed surface of the heat-conduction layer formed in a last execution of the step (d), repeat the steps (b), (c) and (d).

In one embodiment, the method further comprises preparing the dielectric layer before the step (a) is performed.

Other aspects of the present invention are disclosed as illustrated by the embodiments hereinafter.

### BRIEF DESCRIPTION OF THE DRAWINGS

FIG. 1A depicts a thermal interface pad having one heat-conduction layer on a dielectric layer in accordance with one embodiment of the present disclosure, where thermally-conductive fibers in the heat-conduction layer are perpendicular to the dielectric layer.

FIG. 1B depicts a thermal interface pad having one heat-conduction layer on a dielectric layer in accordance with one embodiment of the present disclosure, where thermally-conductive fibers in the heat-conduction layer make an inclination angle less than 90° with respect to the dielectric layer.

FIG. 2A depicts a thermal interface pad having three heat-conduction layers stacked on a dielectric layer in accordance with one embodiment of the present disclosure, where thermally-conductive fibers in each heat-conduction layer are perpendicular to the dielectric layer.

FIG. 2B depicts a thermal interface pad having three heat-conduction layers stacked on a dielectric layer in accordance with one embodiment of the present disclosure, where thermally-conductive fibers in each heat-conduction layer make an inclination angle less than 90° with respect to the dielectric layer.

FIG. 3A depicts a thermal interface pad having two heat-conduction layers respectively on two opposite sides of a dielectric layer in accordance with one embodiment of the present disclosure, where thermally-conductive fibers in each heat-conduction layer are perpendicular to the dielectric layer.

FIG. 3B depicts a thermal interface pad having two heat-conduction layers respectively on two opposite sides of a dielectric layer in accordance with one embodiment of the present disclosure, where thermally-conductive fibers in each heat-conduction layer make an inclination angle less than 90° with respect to the dielectric layer.

FIG. 4A depicts a double-layered stacked thermal interface pad having two heat-conduction layers laterally attached together in accordance with one embodiment of the present disclosure, where thermally-conductive fibers in each heat-conduction layer are perpendicular to the dielectric layer.

FIG. 4B depicts a double-layered stacked thermal interface pad having two heat-conduction layers laterally attached together in accordance with one embodiment of the present disclosure, where thermally-conductive fibers in each heat-conduction layer make an inclination angle less than 90° with respect to the dielectric layer.

FIG. 5 depicts a flowchart showing exemplary steps for fabricating a thermal interface pad.

### DETAILED DESCRIPTION

A thermally-conductive fiber, such as a carbon fiber, is shaped like a rod and can transmit heat efficiently from one end of the fiber to another end thereof. If a number of thermally-conductive fibers are randomly dispersed over a planar substrate and if the fibers are oriented perpendicularly to the substrate, the chance that neighboring fibers contact each other is significantly reduced. Thus, heat conduction is more efficient along a first direction perpendicular to the substrate than a second direction in parallel thereto. Aligning the fibers to orient perpendicularly to the substrate is possible by using an electrostatic technique commonly known as electroflocking. One particular advantage is that electroflocking can be carried out at room temperature, potentially leading to a low manufacturing cost. The present invention is developed based on the aforementioned observations.

A first aspect of the present invention is to provide a thermal interface pad that is thermally-anisotropic. Preferably and advantageously, the thermal interface pad is formed with materials selected to make the thermal interface pad flexible. As mentioned above, this flexible pad has a practical application as an interface between a heat-generating electronic component and a metal heat sink. However, the present invention is not limited to the case that the thermal interface pad disclosed herein is flexible, bendable, deformable or non-rigid; the disclosed thermal interface pad may be rigid or substantially rigid.

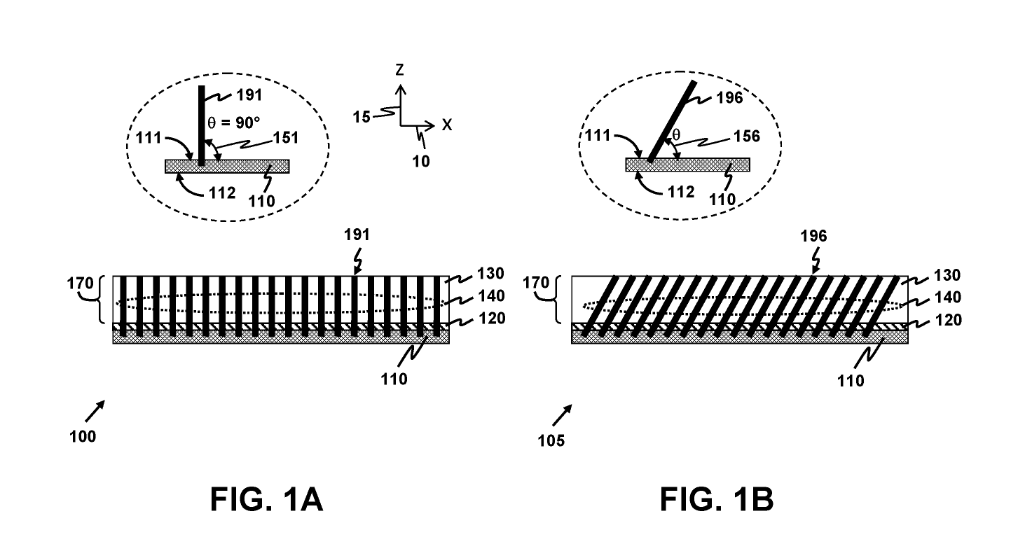

Exemplarily, the thermal interface pad is illustrated with the aid of FIGS. 1A and 1B, both of which depict one of simplest forms of the thermal interface pad in accordance with one embodiment of the present disclosure.

Refer to FIG. 1A. A thermal interface pad 100 comprises a dielectric layer 110 and a first heat-conduction layer 170 integrated with the dielectric layer 110. The dielectric layer 110 is used as a substrate for electroflocking to attach a first plurality of thermally-conductive fibers 140. Another use of the dielectric layer 110 is to prevent high voltage breakdown in operation when the thermal interface pad 100 is attached to an active electronic equipment. Usually, a first adhesive layer 120 is deposited on the dielectric layer 110 to enable the first plurality of fibers 140 to attach to the dielectric layer 110. The first heat-conduction layer 170 is used for transmitting heat to or from the dielectric layer 110. Since practically the dielectric layer 110 is often in contact with a heat source for transferring heat from the heat source to a heat sink via the first heat-conduction layer 170, it is preferred that the dielectric layer 110 is thermally-conductive for facilitating heat transfer between the heat source and the dielectric layer 110.

The dielectric layer 110 has a first side 111 and a second side 112 opposite to the first side 111. Without loss of generality, consider that the first heat-conduction layer 170 is integrated with the dielectric layer 110 on the first side 111 for illustrating the disclosed thermal interface pad 100. The first heat-conduction layer 170 comprises a first sealing agent 130 and the first plurality of thermally-conductive fibers 140. Different fibers in the first plurality of fibers 140 are randomly dispersed in the first sealing agent 130. Random distribution of the first plurality of fibers 140 over the first side 111 of the dielectric layer 110 is realizable also by electroflocking. The first sealing agent 130, which is an adhesive for sealing the first plurality of fibers 140 in the first heat-conduction layer 170, provides encapsulation and mechanical support to the first plurality of fibers 140.

The first plurality of fibers 140 is arranged and oriented to protrude from the dielectric layer 110 for transmitting heat to and from the dielectric layer 110 depending on the temperature difference between the dielectric layer 110 and the first plurality of fibers 140. By orienting the first plurality of fibers 140 to protrude from the dielectric layer 110, each fiber in the first plurality of fibers 140 does not rest on the dielectric layer 110, but makes a non-zero inclination angle with respect to the dielectric layer 110. As used herein in the specification and appended claims, the inclination angle is confined to be an acute angle or a right angle between 0° and 90° inclusively. Take a fiber 191 in FIG. 1A as an example. The fiber 191 makes an inclination angle 151 from the first side 111 of the dielectric layer 110.

In the disclosed thermal interface pad 100, one advantageous arrangement is that different fibers are aligned substantially-unidirectionally to achieve the same inclination angle 151, making the aforementioned different fibers to be substantially parallel so as to discourage neighboring fibers in the first plurality of fibers 140 to contact each other. Since the thermal interface pad 100 is often flexible or bendable, the inclination angle 151 is measured under a reference condition that the dielectric layer is held planar. Another advantageous arrangement of the thermal interface pad 100 is that the first sealing agent 130 has a thermal conductivity less than a thermal conductivity of the first plurality of fibers 140. Preferably, the thermal conductivity of the first sealing agent 130 is substantially less than that of the first plurality of fibers 140. Thus, heat transfer between two non-contact neighboring fibers, which are separated by the first sealing agent 130, is discouraged whereas efficient heat transmission from one end of an individual fiber in the first plurality of fibers 140 to another end thereof is supported. By the aforementioned two advantageous arrangements, heat energy to be transmitted in the first heat-conduction layer 170 is more efficiently transmitted along a first direction perpendicular to the dielectric layer 110 (i.e. along an z-axis 15) than along a second direction in parallel to the dielectric layer 110 (i.e. along an x-axis 10).

Note that depending on the structure of the individual fiber, the individual fiber may be isotropic or anisotropic. In case the individual fiber is anisotropic, the thermal conductivity thereof varies according to the heat propagation direction. (Most often the individual fiber is optimized for heat transmission along an axial direction of the individual fiber.) As mentioned above, it is of interest in the present invention to compare efficiencies of heat propagation along the axial direction of the individual fiber and along a path filled with the first sealing agent 130. It is used herein in the specification and appended claims that, unless otherwise specified, “a thermal conductivity of a plurality of fibers” means a directional thermal conductivity of a representative fiber selected from the plurality of fibers, where the directional thermal conductivity is measured along an axial direction of the representative fiber.

In FIG. 1A, the inclination angle 151 is set to be 90°. This value of inclination angle is realizable by electroflocking in attaching the first plurality of fibers 140 perpendicularly to the dielectric layer 110. Alternatively, it is possible to use a non-90° inclination angle, as shown in FIG. 1B. A thermal interface pad 105 depicted in FIG. 1B is the same as the thermal interface pad 100 of FIG. 1A except that an inclination angle 156 made by the first plurality of thermally-conductive fibers 140 (e.g., a fiber 196 as an example) with respect to the dielectric layer 110 is less than 90°. Usually, the inclination angle 156 is predetermined before the thermal interface pad 105 is fabricated. In practice, preferably the inclination angle 156 is selected from a range of 45° to 90°.

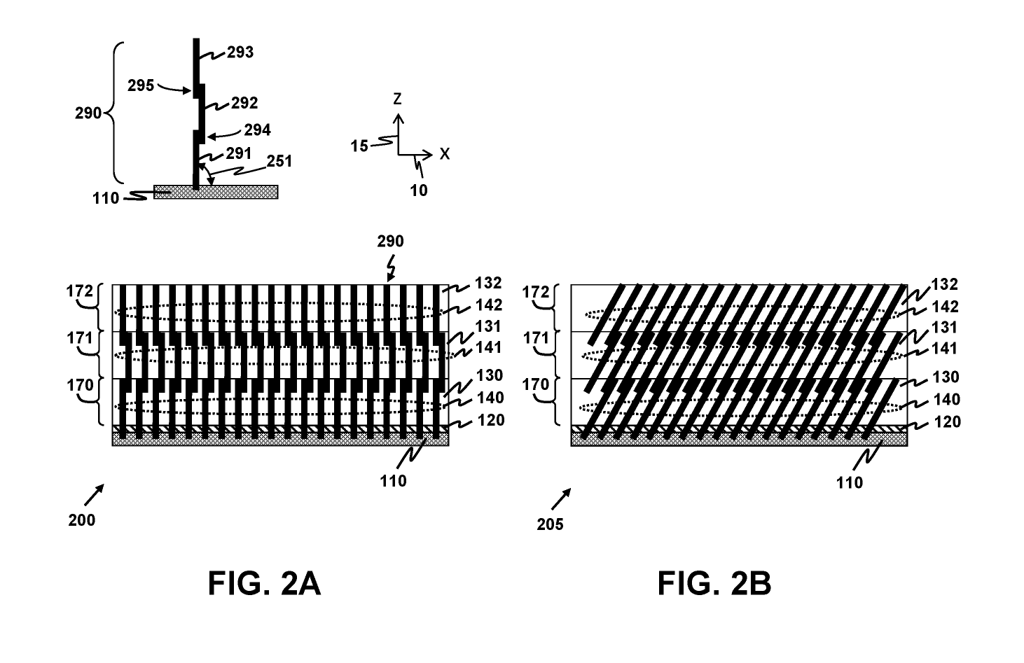

In each of the thermal interface pads 100, 105, there is only one heat-conduction layer. However, having only one heat-conduction layer may make the thermal interface pad too thin to be mechanically robust. To increase the thickness of thermal interface pad, the thermal interface pad 100 or 105 may be modified by incorporating one or more additional heat-conduction layers stacked together on the first heat-conduction layer 170 for transmitting heat from or to the first heat-conduction layer 170. (The direction of heat transmission depends on the temperature gradient.) The number of additional heat-conduction layers that are incorporated varies and can be any positive number as long as the resultant thermal interface pad is realizable. To simplify illustrating a general thermal interface pad having an arbitrary number of additional heat-conduction layers, a specific case of a thermal interface pad having three heat-conduction layers is elaborated. FIGS. 2A and 2B depict thermal interface pads 200, 205, respectively, each having a second heat-conduction layer 171 and a third heat-conduction layer 172 stacked together on top of the first heat-conduction layer 170.

Refer to FIG. 2A. In the thermal interface pad 200, the dielectric layer 110, the first adhesive layer 120 and the first heat-conduction layer 170 are essentially the same as those of the thermal interface pad 100 of FIG. 1A. Note that the first plurality of fibers 140 is perpendicular to the dielectric layer 110 (i.e. an inclination angle 251 being 90°). The second and third heat-conduction layers 171, 172 are similar.

The second heat-conduction layer 171 comprises a second sealing agent 131 and a second plurality of thermally-conductive fibers 141 randomly dispersed in the second sealing agent 131. The second sealing agent 131 has a thermal conductivity less than a thermal conductivity of the second plurality of fibers 141. When the dielectric layer 110 is held planar, different fibers in the second plurality of fibers 141 are aligned substantially-unidirectionally to achieve the same inclination angle 251 with respect to the dielectric layer 110 for discouraging neighboring fibers in the second plurality of fibers 141 to contact each other. As a result, heat energy to be transmitted in the second heat-conduction layer 171 is transmitted more efficiently along the z-axis 15 than along the x-axis 10.

Similarly, the third heat-conduction layer 172 comprises a third sealing agent 132 and a third plurality of thermally-conductive fibers 142 randomly dispersed in the third sealing agent 132. The third sealing agent 132 has a thermal conductivity less than a thermal conductivity of the third plurality of fibers 142. When the dielectric layer 110 is held planar, different fibers in the third plurality of fibers 142 are aligned substantially-unidirectionally to achieve the same inclination angle 251 with respect to the dielectric layer 110 for discouraging neighboring fibers in the third plurality of fibers 142 to contact each other. As a result, heat energy to be transmitted in the third heat-conduction layer 172 is transmitted more efficiently along the z-axis 15 than along the x-axis 10.

The first, second and third conduction layers 170-172 collectively form a plurality of heat-conduction layers. Two respective pluralities of fibers of any two neighboring heat-conduction layers selected from the plurality of heat-conduction layers are interconnected so as to facilitate heat transfer between the two neighboring heat-conduction layers. For illustration of interconnecting fibers in the two neighboring heat-conduction layers, consider a cascade 290 of three fibers 291-293 where the first, second and third fibers 291-293 are respectively selected from the first, second and third pluralities of fibers 140-142. Interconnection of the first and second fibers 291, 292 is obtained by partially overlapping the first and second fibers 291, 292. The first and second fibers 291, 292 overlap on a first region 294. Interconnection of the second and third fibers 292, 293 is similarly obtained by partially overlapping the second and third fibers 292, 293. The second and third fibers 292, 293 overlap on a second region 295.

The first, second and third sealing agents 130-132, although serving the same function, may or may not be the same in composition. The first, second and third pluralities of thermally-conductive fibers 140-142 may or may not be the same in composition. Those skilled in the art will be capable of determining whether or not the same material is used to form these sealing agents 130-132 or these pluralities of fibers 140-142.

In FIG. 2A, the inclination angle 251 is set to be 90°. The thermal interface pad 205 depicted in FIG. 2B uses a non-90° inclination angle. As mentioned above in elaborating the thermal interface pad 105, the inclination angle employed in the thermal interface pad 205 is predetermined before fabrication thereof. In practice, the inclination angle may be selected from a range of 45° to 90°.

Those skilled in the art will appreciate that the thermal interface pad 200 or 205 can be used as a prototype for developing the general thermal interface pad having an arbitrary number of heat-conduction layers according to the teachings disclosed herein. If it is desired to have two heat-conduction layers only, those skilled in the art can obtain the general thermal interface pad by removing the third heat-conduction layer 172 in the prototype thermal interface pad. If more-than-three heat-conduction layers are required, those skilled in the art can obtain the general thermal interface pad by repeating formation of one additional heat-conduction layer on the immediately-previous heat-conduction layer according to the teachings disclosed herein regarding structural details of the third heat-conduction layer 172.

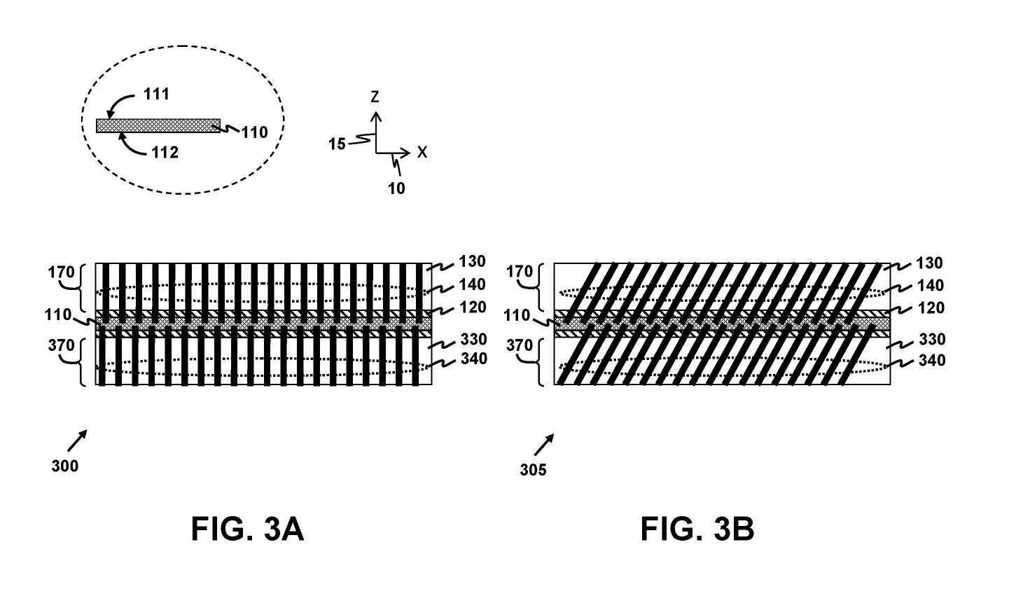

Optionally, it is possible to have another heat-conduction layer on the second side 112 of the dielectric layer 110 rather than having additional heat-conduction layer(s) on top of the first heat-conduction layer 170. FIGS. 3A and 3B depict thermal interface pads 300, 305, respectively, each having one heat-conduction layer on each of two opposite sides of a dielectric layer. Since the two thermal interface pads 300, 305 differ only in their inclination angles of fibers, the illustration hereinafter is focused on the thermal interface pad 300.

Refer to FIG. 3A. In the thermal interface pad 300, the dielectric layer 110, the first adhesive layer 120 and the first heat-conduction layer 170 are essentially the same as those of the thermal interface pad 100 of FIG. 1A. The first plurality of fibers 140 is perpendicular to the dielectric layer 110 so that the inclination angle 151 is 90°. The thermal interface pad 300 further includes a fourth heat-conduction layer 370. The fourth heat-conduction layer 370 comprises a fourth sealing agent 330 and a fourth plurality of thermally-conductive fibers 340 randomly dispersed in the fourth sealing agent 330. The fourth sealing agent 330 has a thermal conductivity less than a thermal conductivity of the fourth plurality of fibers 340. When the dielectric layer 110 is held planar, different fibers in the fourth plurality of fibers 340 are aligned substantially-unidirectionally to achieve the same inclination angle 151 with respect to the dielectric layer 110 for discouraging neighboring fibers in the fourth plurality of fibers 340 to contact each other. As a result, heat energy to be transmitted in the fourth heat-conduction layer 370 is transmitted more efficiently along the z-axis 15 than along the x-axis 10.

Usually, a second adhesive layer 320 is deposited on the second side 112 of the dielectric layer 110 to enable the fourth plurality of fibers 340 to attach to the dielectric layer 110 during electroflocking.

The first and fourth sealing agents 130, 330, although serving the same function, may or may not be the same in composition. The first and fourth pluralities of thermally-conductive fibers 140, 340 may or may not be the same in composition. Those skilled in the art will be capable of determining whether or not the same material is used to form these sealing agents 130, 330 or these pluralities of fibers 140, 340.

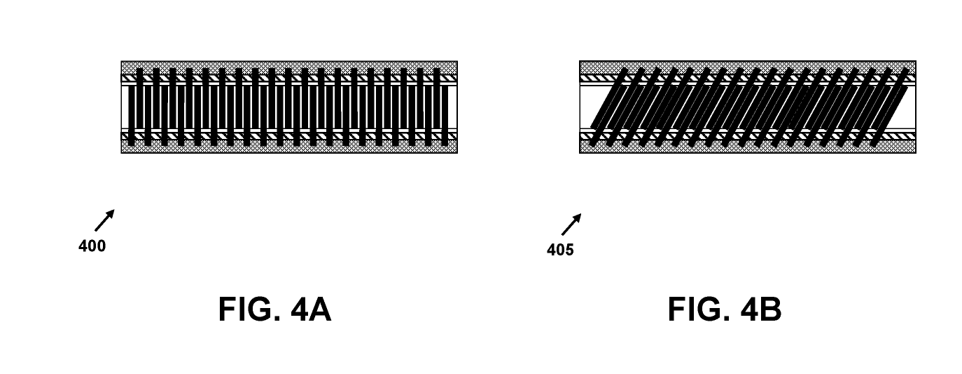

In one embodiment, two units of the thermal interface pad 100 (or 105) are laterally stacked together with one unit inverted with respect to another unit to form a double-layered stacked thermal interface pad 400 (or 405) as shown in FIG. 4A (or FIG. 4B).

Practical realization of the thermal interface pads 100, 105, 200, 205, 300, 305 is further elaborated as follows.

Preferably, the dielectric layer 110 has a thickness between 50 μm to 500 μm inclusively, more preferably between 50 μm to 200 μm inclusively. Such thickness enables the dielectric layer 110 to withstand a high voltage of 0.1 kV-1 kV for achieving voltage-breakdown protection during practical operation as a thermal interface pad between a heat source and a metal heat sink. The dielectric layer 110 may contain silicone or epoxy resin to form a polymer network that acts as a bulk of the dielectric layer 110. Note that silicone and epoxy resin may be made thermally conductive. The dielectric layer 110 may further contain fillers dispersed in the polymer network. Examples of the fillers include aluminum oxide, aluminum nitride, aluminum hydroxide, boron nitride (BN), one or more types of ceramic particles, and a combination thereof. In one practical example, the dielectric layer 110 contains the following components in weight percentage: 5-10% methyl vinyl silicone rubber, 30-50% vinyl silicone oil, 30-60% polymethylsiloxane, 300-600% aluminum oxide (Al₂O₃), 100-200% aluminum hydroxide (Al(OH)₃), 3-5% silicone oil, and 1-2% platinum catalyst.

The first and second adhesive layers 120, 320 deposited on the dielectric layer 110 each may have a thickness in a range of 10 μm to 150 μm, more preferably in a range of 50 μm to 100 μm. Polydimethysiloxane (PDMS) may be used as the first and second adhesive layers 120, 320.

Fibers in the first to fourth pluralities of thermally-conductive fibers 140-142, 340 may be selected from carbon fibers, carbon nanotubes etc. Particularly, pitch type carbon fibers and carbon nanotubes are preferred. Furthermore, thermally-conductive fillers, such as aluminum oxide, aluminum nitride, aluminum hydroxide, boron nitride, etc., may be incorporated in the first to fourth pluralities of thermally-conductive fibers 140-142, 340.

Preferably and desirably, all thermally-conductive fibers in a thermal interface pad account for 50-90 weight % of the whole thermal interface pad.

The first to fourth sealing agents 130-132, 330 are adhesives for sealing respective pluralities of fibers in respective heat-conduction layers. These sealing agents 130-132, 330 may be formed by silicone or epoxy resin. A suggested coating thickness is from 250 μm to 1000 μm, more preferably from 250 μm to 700 μm. These sealing agents 130-132, 330 may further contain fillers such as aluminum oxide, aluminum nitride, aluminum hydroxide, boron nitride, one or more types of ceramic particles, and a combination thereof. In one practical example, a sealing agent contains the following components in weight percentage: 80-90% vinyl silicone oil, 10-15% silicone oil, and 1-2.5% platinum catalyst.

A second aspect of the present invention is to provide a method for fabricating the thermal interface pad that is disclosed above in the first aspect of the present invention.

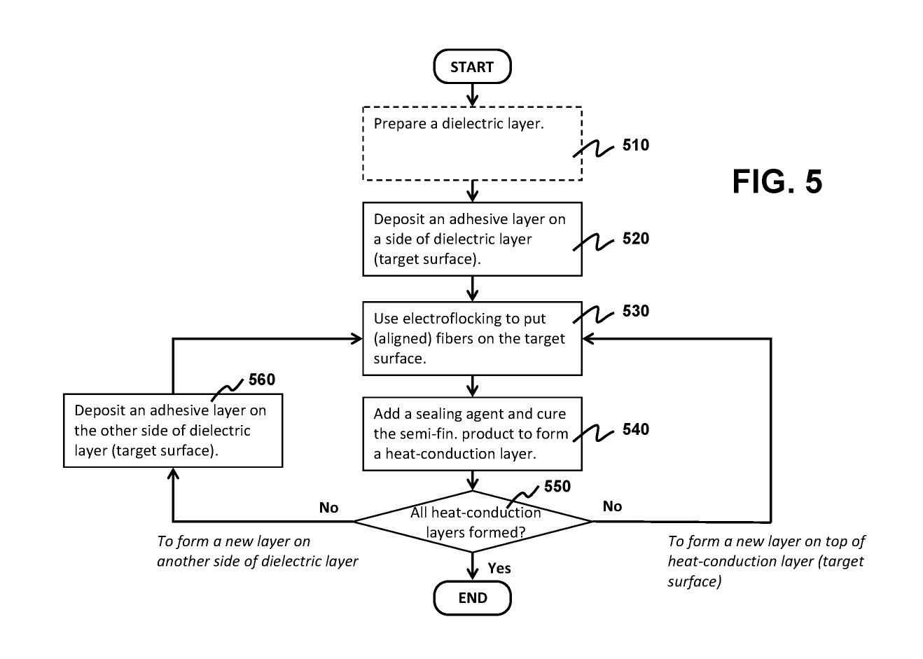

The method is illustrated with the aid of FIG. 5. FIG. 5 depicts a flowchart illustrating an exemplary process flow for fabricating a thermal interface pad as disclosed above in the present disclosure.

Before the thermal interface pad is fabricated, a dielectric layer is made available by acquiring it or preparing it. The method includes an optional step 510 of preparing the dielectric layer.

After the dielectric layer is available, an adhesive layer is deposited on a first side of the dielectric layer in a step 520. The first side is regarded as a target surface for electroflocking.

In a step 530, electroflocking is employed to bind a plurality of thermally-conductive fibers on the target surface, and to cause different fibers in the plurality of fibers to be aligned substantially-unidirectionally to achieve a predetermined inclination angle with respect to the dielectric layer. Thereby, neighboring fibers in the plurality of fibers are discouraged to contact each other. In applying an electrostatic voltage to the dielectric layer to attach fibers thereon, the voltage is suggested to be between 10 kV to 100 kV inclusively, more preferably between 50 kV to 80 kV inclusively. In attaching thermally-conductive fibers to the dielectric layer, it is required to control the electroflocking process to prevent the fibers from punching through the dielectric layer. Preferably, the fibers penetrate into the dielectric layer, and the fiber penetration depth is controlled to be ¼ to ¾ of the thickness of the dielectric layer.

After the plurality of fibers is attached to the target surface in the step 530, a sealing agent is used to seal the plurality of fibers in a step 540. In the step 540, the sealing agent is deposited on the plurality of fibers, and is arranged to immerse into gaps among the different fibers in the plurality of fibers to form a heat-conduction layer. Curing is usually used to allow the sealing agent to immerse into the gaps among the fibers. The whole thermal interface pad may be cured at a high temperature, or at room temperature at the expense of a longer curing time. Preferably, the thermal curing condition is from 80° C. to 150° C. Vacuum may be applied to the curing process to achieve an optimal curing performance. A preferable vacuum condition is that the pressure is reduced to less than or equal to −0.009 MPa.

After the step 540 is done, a step 550 of checking whether there is any target surface that requires fabricating an additional heat-conduction layer thereon. When it is determined that the target surface is a second side of the dielectric layer, a second adhesive layer is deposited onto the target surface, and then the steps 530 and 540 are repeated. When it is determined that the target surface is an exposed surface of the heat-conduction layer formed in a last execution of the step 540, repeat the steps 530 and 540. Coating an adhesive layer on the aforementioned exposed surface is not required because the sealing agent in the heat-conduction layer is already an adhesive. Note that the step 550 is not required if it is known to fabricate the thermal interface pad 100 or 105, which has the first heat-conduction layer 170 only.

Some examples of procedures for fabricating thermal interface pad prototypes are provided as follows for further illustrating the above-disclosed method. Experimental results of the fabricated prototypes are also presented.

A first prototype based on the thermal interface pad 100 was fabricated by the following procedure. The first prototype has one heat-conduction layer.
(1) Step 510:
   Weighed 2 g PDMS and mixed with 12 g ceramic powder. After the mixing, 2 g PDMS curing agent was added and mixing was performed. Then the dielectric ink was obtained.
   Used a blade to blade the dielectric ink on the polyethylene terephthalate (PET) with a thickness of 150±50 μm. Put the dielectric layer into an oven to dry and cured at 90±10° C. for 10 minutes.
(2) Step 520: After the dielectric layer was cured, 20-50 μm PDMS was coated on the dielectric layer surface as the carbon fiber flocking base.
(3) Step 530: Put the layer on an electro-flocking machine with a voltage of 30-50±5 kV for 1 minute.
(4) Step 540:
   Cured the sample at 90±10° C. for 10 minutes.
   Weighed 2 g PDMS and mixed with 2.4 g Al(OH)₃ powder. After mixing, added 2 g PDMS curing agent and mixed. Then the coating ink was obtained.
   After the sample was cured, took the sample out and prepared the Al(OH)₃ coating ink to coat on the carbon fiber surface.
   Coated the coating ink on the sample surface with coating thickness around 800±10 μm. Put the sample in vacuum at room temperature for more than 1 hour to make the coating ink immerse into the carbon fibers' gap, or kept the sample static at room temperature for 6-12 hours to ensure that the coating ink immersed into the carbon fibers' gap.
   Kept the sample at 90±10° C. for 10 minutes to cure. The carbon fibers were at the vertical direction of the sample.

A second prototype based on the thermal interface pad 200 with only the first and second heat-conduction layers 170, 171 was fabricated by the following procedure. The second prototype has two heat-conduction layers on one side of the dielectric layer.
(1) Step 510:
   Weighed 2 g PDMS and mixed with 12 g ceramic powder. After the mixing, 2 g PDMS curing agent was added and mixing was performed. Then the dielectric ink was obtained.
   Used a blade to blade the dielectric ink on the PET with a thickness of 150±50 μm. Put the dielectric layer into an oven to dry and cured at 90±10° C. for 10 minutes.
(2) Step 520: After the dielectric layer was cured, 20-50 μm PDMS was coated on the dielectric layer surface as the carbon fiber flocking base.
(3) Step 530: Put the layer on an electro-flocking machine with a voltage of 30-50±5 kV for 1 minute.
(4) Step 540:
   Cured the sample at 90±10° C. for 10 minutes.
   Weighed 2 g PDMS and mixed with 2.4 g Al(OH)₃ powder. After mixing, added 2 g PDMS curing agent and mixed. Then the coating ink was obtained.
   After the sample was cured, took the sample out and prepared the Al(OH)₃ coating ink to coat on the carbon fiber surface.
   Coated the coating ink on the sample surface with coating thickness around 800±10 μm.
(5) Step 530: Put the sample on the electro-flocking machine with a voltage of 30-50±5 kV for 1 minute.
(6) Step 540:
   Put the sample in vacuum at room temperature for more than 1 hour to make the coating ink immerse into the carbon fibers' gap, or put the sample at room temperature for 6-12 hours to ensure the coating ink immerse into the carbon fibers' gap.
   Cured the sample at 90±10° C. for 10 minutes.
   Coated the surface with the coating ink at a thickness around 1400±20 μm.
   Put the sample in vacuum at room temperature for more than 1 hour to make the coating ink immerse into the carbon fibres' gap, or put the sample at room temperature for 6-12 hours to ensure the coating ink immerse into the carbon fibers' gap.
   Cured the sample at 90±10° C. for 10 minutes.

A third prototype based on the thermal interface pad 300 was fabricated by the following procedure. The third prototype has two heat-conduction layers, one on a first side of the dielectric layer, another one on a second side thereof
(1) Step 510:
   Weighed 2 g PDMS and mixed with 12 g ceramic powder. TAfter the mixing, 2 g PDMS curing agent was added and mixing was performed. Then the dielectric ink was obtained.
   Used a blade to blade the dielectric ink on the PET with a thickness of 150±50 μm. Put the dielectric layer into an oven to dry and cured at 90±10° C. for 10 minutes.
(2) Step 520: After the dielectric layer was cured, 20-30 μm PDMS was coated on the dielectric layer surface as the carbon fiber flocking base.
(3) Step 530: Put the layer on an electro-flocking machine with a voltage of 30-50±5 kV for 1 minute.
(4) Step 540:
   Cured the sample at 90±10° C. for 10 minutes.
   Weighed 2 g PDMS and mixed with 2.4 g Al(OH)₃ powder. After mixing, added 2 g PDMS curing agent and mixed. Then the coating ink was obtained.
   After the sample was cured, took the sample out and prepared the Al(OH)₃ coating ink to coat on the carbon fiber surface.
   Coated the coating ink on the sample surface with coating thickness around 800±10 μm.
   Put the sample in vacuum at room temperature for more than 1 hour to make the coating ink immerse into the carbon fibers' gap, or put the sample at room temperature for 6-12 hours to ensure the coating ink immerse into the carbon fibers' gap.
(5) Step 560: Coated 20-30 μm PDMS on the second side of the dielectric layer as the carbon fiber flocking base.

(6) Step 530: Put the sample coated with carbon fiber flocking base exposed to the electro-flocking machine with a voltage of 30-50±5 kV for 1 minute.
(7) Step 540:
   Cured the sample at 90±10° C. for 10 minutes.
   Coated the surface with the coating ink at a thickness around 1400±20 μm.
   Put the sample in vacuum at room temperature for more than 1 hour to make the coating ink immerse into the carbon fibres' gap, or put the sample at room temperature for 6-12 hours to ensure the coating ink immerse into the carbon fibers' gap.
   Cured the sample at 90±10° C. for 10 minutes.

A fourth prototype based on the thermal interface pad 200 with the first, second and third heat-conduction layers 170-172 was fabricated by the following procedure. The fourth prototype has three heat-conduction layers on one side of the dielectric layer.
(1) Step 510:
   Weighed 2 g PDMS and mixed with 12 g ceramic powder. After the mixing, 2 g PDMS curing agent was added and mixing was performed. Then the dielectric ink was obtained.
   Used a blade to blade the dielectric ink on the PET with a thickness of 150±50 μm. Put the dielectric layer into an oven to dry and cured at 90±10° C. for 10 minutes.
(2) Step 520: After the dielectric layer was cured, 20-30 μm PDMS was coated on the dielectric layer surface as the carbon fiber flocking base.
(3) Step 530: Put the layer on an electro-flocking machine with a voltage of 30-50±5 kV for 1 minute.
(4) Step 540:
   Cured the sample at 90±10° C. for 10 minutes.
   Weighed 2 g PDMS and mixed with 2.4 g Al(OH)₃ powder. After mixing, added 2 g PDMS curing agent and mixed. Then the coating ink was obtained.
   After the sample was cured, took the sample out and prepared the Al(OH)₃ coating ink to coat on the carbon fiber surface.
   Coated the coating ink on the sample surface with coating thickness around 800±10 μm.
(5) Step 530: Put the sample on the electro-flocking machine with a voltage of 30-50±5 kV for 1 minute.
(6) Step 540:
   Put the sample in vacuum at room temperature for more than 1 hour to make the coating ink immerse into the carbon fibers' gap, or put the sample at room temperature for 6-12 hours to ensure the coating ink immerse into the carbon fibers' gap.
   Cured the sample at 90±10° C. for 10 minutes.
   Coated the surface with the coating ink at a thickness around 1400±20 μm.
   (7) Step 530: Put the sample on the electro-flocking machine with a voltage of 30-50±5 kV for 1 minute.
   (8) Step 540:
Put the sample in vacuum at room temperature for more than 1 hour to make the coating ink immerse into the carbon fibres' gap, or put the sample at room temperature for 6-12 hours to ensure the coating ink immerse into the carbon fibers' gap.
Cured the sample at 90±10° C. for 10 minutes.
Coated the surface with the coating ink at a thickness around 2000±20 μm.
Put the sample in vacuum at room temperature for more than 1 hour to make the coating ink immerse into the carbon fibres' gap, or put the sample at room temperature for 6-12 hours to ensure the coating ink immerse into the carbon fibers' gap.
Cured the sample at 90±10° C. for 10 minutes.

Thermal and electrical properties of the fabricated prototypes were measured. The measured properties of the first, third and fourth prototypes are listed in the following table. Since the second and third prototypes each have two heat-conduction layers, and since the only difference between the two prototypes is in the dielectric layer location, the properties of the two prototypes would be similar, and the measurement results of the second prototype are not listed below. Values of thermal conductivity as listed below were measured along the direction perpendicular to the dielectric layer (e.g., along the z-axis 15 shown in FIG. 1A).

| | First prototype | | |
|---|---|---|---|
| | (with one heat- | Third prototype | Fourth prototype |
| | conduction | (with two heat- | (with three heat- |
| | layers) | conduction layer) | conduction layers) |
| Density | 1.3 | 1.3 | 1.3 |
| Thermal | 5.0 | 9.02 | 14.5 |
| conductivity | | | |
| (W/mK) | | | |
| Thermal | ≤0.15 | ≤0.15 | ≤0.15 |
| resistance | | | |
| (° C. in²/W) | | | |
| Dielectric | 1.0 | 1.2 | 1.2 |
| breakdown | | | |
| voltage (kV) | | | |

As a remark, the present invention is different from the thermally-anisotropic polymer film of WO2016/178120A1 in the following aspect. The polymer film comprises a polyester forming a matrix, and a plurality of anisotropic primary filler particles dispersed within the matrix. Thermal anisotropy is formed by sequentially or simultaneously biaxially stretching a thermally-isotropic film in two preferred directions so as to force the anisotropic primary filler particles to orient away from the film plane. Since polyester is often less thermally-conductive than the filler particles, and since the polyester material of the film rather than the filler particles directly contacts a heat source, the transmission of heat from the heat source to the polyester film is restricted by the thermal conductivity of the polyester material. On the other hand, the thermal interface pad 100 includes the dielectric layer 110, which can be selected to be thermally-conductive. Furthermore, the first plurality of thermally-conductive fibers 140 protrudes from the dielectric layer 110 for transmitting heat therefrom. When the heat source is in contact with the dielectric layer 110 of the thermal interface pad 100, heat is efficiently transferred to the first plurality of fibers 140 via the dielectric layer 110.

The present invention may be embodied in other specific forms without departing from the spirit or essential characteristics thereof. The present embodiment is therefore to be considered in all respects as illustrative and not restrictive. The scope of the invention is indicated by the appended claims rather than by the foregoing description, and all changes that come within the meaning and range of equivalency of the claims are therefore intended to be embraced therein.

What is claimed is:

1. A thermal interface pad comprising:
a dielectric layer having a first side and a second side opposite thereto; and
a first heat-conduction layer integrated with the dielectric layer on the first side comprising a first sealing agent and a first plurality of thermally-conductive fibers randomly dispersed in the first sealing agent, the first plurality of fibers being arranged and oriented to protrude from the dielectric layer for transmitting heat therefrom or thereto, the first sealing agent having a thermal conductivity less than a thermal conductivity of the first plurality of fibers, wherein when the dielectric layer is held planar, different fibers in the first plurality of fibers are aligned substantially-unidirectionally to achieve a predetermined inclination angle with respect to the dielectric layer for discouraging neighboring fibers in the first plurality of fibers to contact each other, causing heat energy to be transmitted in the first heat-conduction layer more efficiently along a first direction perpendicular to the dielectric layer than along a second direction in parallel thereto.

2. The thermal interface pad of claim 1, wherein the predetermined inclination angle is in a range of 45° to 90°.

3. The thermal interface pad of claim 1, wherein the dielectric layer contains silicone or epoxy resin.

4. The thermal interface pad of claim 3, wherein the dielectric layer further contains fillers composed of aluminum oxide, aluminum nitride, aluminum hydroxide, boron nitride, one or more types of ceramic particles, or a combination thereof.

5. The thermal interface pad of claim 1 further comprising a first adhesive layer on the first side for binding the first plurality of fibers to the dielectric layer.

6. The thermal interface pad of claim 1, wherein the first plurality of fibers includes carbon fibers, carbon nanotubes or a combination thereof.

7. The thermal interface pad of claim 1, wherein the first sealing agent contains silicone or epoxy resin.

8. The thermal interface pad of claim 7, wherein the first sealing agent further contains fillers composed of aluminum oxide, aluminum nitride, aluminum hydroxide, boron nitride, one or more types of ceramic particles, or a combination thereof.

9. The thermal interface pad of claim 1 further comprising:
one or more additional heat-conduction layers stacked together on the first heat-conduction layer for transmitting heat therefrom or thereto, the first heat-conduction layer and the one or more additional heat-conduction layers forming a plurality of heat-conduction layers, an individual additional heat-conduction layer comprising a respective sealing agent and a respective plurality of thermally-conductive fibers randomly dispersed in the respective sealing agent, the respective sealing agent having a thermal conductivity less than a thermal conductivity of the respective plurality of fibers, wherein:
when the dielectric layer is held planar, different fibers in the respective plurality of fibers are aligned substantially-unidirectionally to achieve the predetermined inclination angle with respect to the dielectric layer for discouraging neighboring fibers in the respective plurality of fibers to contact each other, causing heat energy to be transmitted in the individual additional heat-conduction layer more efficiently along the first direction than along the second direction; and
the two respective pluralities of fibers of any two neighboring heat-conduction layers selected from the plurality of heat-conduction layers are interconnected so as to facilitate heat transfer between the two neighboring heat-conduction layers.

10. The thermal interface pad of claim 9, wherein the two respective pluralities of fibers of the two neighboring heat-conduction layers are mutually partially-overlapped for achieving interconnection.

11. The thermal interface pad of claim 9, wherein respective sealing agents in the plurality of heat-conduction layers are made of a same material.

12. The thermal interface pad of claim 1 further comprising:
a second heat-conduction layer integrated with the dielectric layer on the second side comprising a second sealing agent and a second plurality of thermally-conductive fibers randomly dispersed in the second sealing agent, the second plurality of fibers being arranged and oriented to protrude from the dielectric layer for transmitting heat therefrom or thereto, the second sealing agent having a thermal conductivity less than a thermal conductivity of the second plurality of fibers, wherein when the dielectric layer is held planar, different fibers in the second plurality of fibers are aligned substantially-unidirectionally to achieve the predetermined inclination angle with respect to the dielectric layer for discouraging neighboring fibers in the second plurality of fibers to contact each other, causing heat energy to be transmitted in the second heat-conduction layer more efficiently along the first direction than along the second direction.

13. The thermal interface pad of claim 12, wherein the first and second sealing agents are made of a same material.

14. The thermal interface pad of claim 1, wherein the dielectric layer is thermally-conductive.

15. The thermal interface pad of claim 1, wherein at least the dielectric layer and the first sealing agent are selected to be deformable so as to configure the thermal interface pad to be flexible.

16. A method for fabricating a thermal interface pad comprising the steps of:
(a) depositing a first adhesive layer on a first side of a dielectric layer, whereby the first side is regarded as a target surface for electroflocking;
(b) using electroflocking to bind a plurality of thermally-conductive fibers on the target surface and to cause different fibers in said plurality of fibers to be aligned substantially-unidirectionally to achieve a predetermined inclination angle with respect to the dielectric layer for discouraging neighboring fibers in said plurality of fibers to contact each other;
(c) depositing a sealing agent on said plurality of fibers; and
(d) arranging the sealing agent to immerse into gaps among the different fibers in said plurality of fibers to form a heat-conduction layer.

17. The method of claim 16 further comprising the steps of:
(e) after the step (d) is done, checking whether there is any target surface that requires fabricating an additional heat-conduction layer thereon; and
(f) when it is determined that the target surface is a second side of the dielectric layer, depositing a second adhesive layer onto the target surface and repeating the steps (b), (c) and (d).

18. The method of claim 16 further comprising the steps of:
(g) after the step (d) is done, checking whether there is any target surface that requires fabricating an additional heat-conduction layer thereon; and
(h) when it is determined that the target surface is an exposed surface of the heat-conduction layer formed in a last execution of the step (d), repeating the steps (b), (c) and (d).

19. The method of claim 1 further comprising the step of:
(i) preparing the dielectric layer before the step (a) is performed.
